(19) United States
(12) Patent Application Publication
(10) Pub. No.: US 2025/0311088 A1
(43) Pub. Date: Oct. 2, 2025

(54) COMPONENT CARRIER, METHOD FOR MANUFACTURING OF A COMPONENT CARRIER AND PACKAGE

(71) Applicant: AT&S (Chongqing) Company Limited, Chongqing (CN)

(72) Inventors: Yang SONG, Penang (MY); Dick YANG, Chongqing (CN); Yongpeng HA, Chongqing (CN); Yang CHEN, Chongqing (CN)

(73) Assignee: AT&S (Chongqing) Company Limited, Chongqing (CN)

(21) Appl. No.: 19/085,198

(22) Filed: Mar. 20, 2025

(30) Foreign Application Priority Data
Mar. 29, 2024 (CN) 202410381307.4

(51) Int. Cl. H05K 1/02; G01N 25/18; H05K 1/11; H05K 3/00

(52) U.S. Cl. CPC H05K 1/0213; G01N 25/18; H05K 1/11; H05K 3/00

(57) ABSTRACT

A component carrier having a stack with a stacking direction, wherein said stack has at least one electrically conductive layer structure, at least one electrically insulating structure, a first main surface and a second main surface. The first main surface and the second main surface are provided one above the other in a stacking direction and are opposed one to each other. A first lateral wall and a second lateral wall are provided between and connect the opposed first and second main surfaces. At least in a planarized state of said stack, in at least a first extension direction, an extension of the first main surface is different from an extension of the second main surface.

This application claims the benefit of Chinse Application CN202410381307.4, filed on Mar. 29, 2024, the contents of which are incorporated herein by reference.

### FIELD OF THE INVENTION

The present invention generally relates to a component carrier comprising a stack with a stacking direction, wherein the stack comprises at least one electrically conductive layer structure, at least one electrically insulating structure, a first main surface, and a second main surface, wherein said first main surface and said second main surface are provided one above the other in a stacking direction and being opposed one to each other, and wherein a first lateral wall and a second lateral wall between said first and second main surfaces connecting said opposed main surfaces.

Further, the present invention relates to a method for manufacturing a component carrier, in particular to a method for a component carrier as described above.

Additionally, the present invention relates to a package comprising a component carrier, in particular a component carrier as described above and/or manufactured by a method as described above.

### TECHNICAL BACKGROUND

Component carriers as described above, methods for manufacturing such component carriers and packages comprising at least one of this kind of component carrier are well-known from the state of the art. Such component carriers often play an important role in packages or other assemblies in the thermal treatment of these devices such as some function test for the component carrier with temperature, in particular for heat conductivity with the component carrier, wherein the component carriers may be coupled, in particular heat conductively, to a heat sink. For proper test applied by temperature, a proper connection between the component carrier and the heat sink has to be established. The connection quality inter alia depends on the component carrier, for example on the size, shape, design and quality of the connecting and/or contact areas and/or contact points of the component carrier, in particular of its external surfaces. These in turn, are inter alia affected by the manufacturing process of the component carrier.

From prior art different measures are known, in particular different component carriers and different methods for manufacturing of component carriers, to address these issues or to reduce the problems caused by these issues.

Such component carriers may in particular comprise at least one stack which is made from a panel comprising several panel stacks, in particular an array of panel stacks, wherein the stack has been cut out from the panel and thereby been separated from the other stacks by a mechanical separation process, for example by dicing or laser cutting or sawing.

Separating parts of a panel or a “substrate” by cutting is also an often used method in the technical field of semiconductor manufacturing and known from prior art. However, design, material and applications, and also process conditions and parameters in semiconductor manufacturing are different from component carrier manufacturing and are therefore usually not applicable or suitable or only with additional measures for component carriers and/or component manufacturing. Hence, for improvement of component carriers and/or of methods for manufacturing component carriers, own solutions have to be developed.

Against this background, the technical problem underlying the present invention is to provide an alternative component carrier, in particular an improved component carrier, an alternative method for manufacturing a component carrier, in particular an improved method, and an alternative, in particular improved, package comprising a respective component carrier, wherein in particular a component carrier may be provided configured to enable an improved contact with components mounted on the component carrier and/or with another component carrier which may support the component carrier and may be connected with the component carrier. Additionally, also a good connection may be ensured with a heat sink and therewith improved heat conductivity between the component carrier and the heat sink, what may be advantageous for a burn in test. A provided component carrier, method and/or package may in particular allow to reduce the failure of risk of so-called “Unit Burn In (UBI)” for the defined pattern to be tested, in particular to reduce a failure rate in a so-called UBI-test (in the following “UBT”).

Apart from that, a UBT can help to detect early failure, random failure, and/or wear out failure, in particular in an early stage of manufacturing. The earlier and more accurately a failure can be detected, the higher the probability is that a product with real failure will be not proceeded with next procedures and finally flow to the end market. As a result, the overall quality (ration) of the final product delivered to the end market can be increased.

In the context of the present application an “UBT” or so-called “Unit Burn In-test” may denote a test comprising a supervised application of electrical and/or thermal stress on an electrical device to induce inherent failures. Burn-in testing is a prediction method used to identify and discard defective solid-state electronic components before they reach the market or get assembled in electronic products. Burn-in testing has become a critical industry procedure to ensure quality. A UBT may in particular refer to the burn in test by unit level. The burn-in test is one way to improve reduce early failure rates. Latent defects in electronic products can be detected from burn-in tests. The latent defects become prominent when the device starts operating due to the applied voltage stress and heating. In burn-in tests, the chips, PCBs, or semiconductor devices may be tested under elevated temperature, voltage, and/or power cycling conditions. The test in particular accelerates the appearance of the latent defects in the device by forcing it to undergo failure conditions under supervision. The load capacity of the electronic product may be evaluated by applying stresses such as high voltage and/or temperature. The burn-in test may be conducted on each component of the production batch to ensure manufacturing standards are met and the component is reliable, wherein the components to be tested are generally tested on a random basis, i.e., not every component is tested but a representative number of components of the respective batch on a random basis. The burn-in test is a very appropriate method to weed out initial high potential failures in an electronic product. The devices that survive the burn-in test are usually high-quality pieces that are free of latent defects and can be trusted to be incorporated in the final product assembly. In particular, dielectric failures, metallization failures, electromigration, and conductor failures can be detected during burn-in testing of electronic products.

### SUMMARY OF THE INVENTION

With respect to the above, a component carrier, a method for manufacturing a component carrier and a package comprising a component carrier.

A component carrier according to the first aspect of the present invention comprises a stack with a stacking direction, wherein said stack comprises at least one electrically conductive layer structure, at least one electrically insulating structure, a first main surface, and a second main surface, wherein said first main surface and said second main surface are provided one above the other in a stacking direction and being opposed one to each other, and wherein a first lateral wall and a second lateral wall between said first and second main surfaces are connecting said opposed main surfaces. At least in a planarized state of said stack, in at least a first extension direction an extension of the first main surface is different from an extension of the second main surface.

With a component carrier designed like this and according to the present invention the ability to perform reliable connections can significantly be increased. For example, the ability of the component carrier to establish reliable heat conductive connections can be increased. The inventive design of the component carrier according to the present invention may in particular support reducing the risk of so-called “Unit Burn In”, in particular reducing a failure rate in a UBT.

For some component carriers, in addition or alternatively, also more reliable electrical connections can be achieved, in particular improved electrical connections ensuring desired signal transmission performance, low-loss power and/or ground delivery. The ability to establish more reliable connections. in particular more reliable thermal and/or electrical connections, may in particular be detected in “Unit Burn In”-Tests (“UBT”).

In particular an improved component carrier may be provided with improved UBT results.

By the different extensions of the two main surfaces of the component carrier in particular a component carrier may be provided, having a defined and advantageous shape in at least one state and/or being capable of being deformed into a defined and advantageous shape, in particular during or for a step in a further manufacturing process in which the component carrier is, for example, being coupled with a heat sink and/or an electrical component.

As a result, an advantageous improvement of establishing connections and coupling with other parts may be achieved which may further lead to improved UBT results and/or higher accuracy of UBT results. As a result, the accuracy of test in the package can be improved. That means, the quality of the final IC package with such a component carrier can be improved.

By this design, in particular in an advantageous manner, a curved shape component carrier and/or a component carrier deformable into a curved shape, in particular into a concave or convex shape, which is a very advantageous shape for this purpose, can be provided.

In the context of the present application, the term “component carrier” may particularly denote any support structure which is capable of accommodating one or more components thereon and/or therein for providing mechanical support and/or electrical connectivity. A component carrier may also be applied by thermal treatment to measure if the component carrier has a good reliability or quality, wherein the component carrier may in particular assembled with components as a IC package to connect with a heat test tooling in a thermal test, preferably tested in the UBI test. In other words, a component carrier may be configured as a mechanical and/or electronic carrier for components.

In particular, a component carrier may be one of or may be configured as a printed circuit board (PCB), an interposer, in particular an organic interposer, and an IC (integrated circuit) substrate. A component carrier may also be a hybrid board combining different ones of the above-mentioned types of component carriers.

A component carrier may in particular comprise one or more stacks and/or sub-stacks, wherein each stack in particular may comprise a plurality of layer structures, preferably at least one electrically conductive layer structure, and/or at least one insulating layer structure. The insulating layer structure may comprise at least one organic structure and/or at least one inorganic structure.

In at least one embodiment, the component carrier is in particular a laminate-type component carrier. In such an embodiment, the component carrier may in particular be a compound of multiple layer structures which are stacked and connected together by applying a pressing force and/or heat, in particular with simultaneous application of vacuum or a significant amount of negative pressure.

In the context of the present application, the term “stack” may particularly denote an arrangement of multiple layer structures which are preferably planar and mounted in parallel on top of one another. Some of the layer structures of the stack described herein may be stacked directly onto each other, that means with not further layer structure or component in between or indirectly, wherein between other layer structures described in the present application, further layer structures or components or the like may be arranged which are not described in the present application unless explicitly described to the contrary.

In the context of the present application, the term “stacking direction” may particularly refer to a direction perpendicular to a planar extension of at least one layer structure of the stack.

In the context of the present application, the term “layer structure” may particularly denote a continuous layer, a patterned layer or a plurality of non-consecutive islands within a common plane. A layer structure can comprise at least one protruding element such as, for example, one or more solder bumps, copper bumps, pillars or other bonding structures like these, wherein the at least one protruding element may in particular protrude beyond the surface of a layer structure. In addition or alternatively, a layer structure may also comprise at least one recess and/or at least one cavity.

In the context of the present application, the term “electrically conductive layer structure” may particularly denote a layer structure which is electrically conductive. An electrically conductive layer structure may in particular comprise one or more conductive pathways, tracks, and/or signal traces and/or through connections such as vias and holes and/or interconnection structures for interconnection of the layers and/or for connection with other elements and/or components such as bumps, pillars or the like. These electrically conductive structures may for example be etched from copper sheets and may, for example, be applied onto an electrically non-conductive or electrically insulating layer structure, which in at least one embodiment the component carrier may comprise additionally. In some embodiments, an electrically conductive structure may, for example, be applied using a printing process, for example by using a 3D printing process. In some embodiments, an electrically conductive structure may as well be deposited with a seed layer and plated with at least one trace, wherein the seed layer is later etched.

In at least one embodiment, the at least one electrically conductive layer structure of the component carrier comprises at least one of the following group consisting of: copper, aluminum, nickel, silver, gold, palladium, tungsten, titanium, chromium and magnesium and/or an alloy comprising at least one material component of the aforementioned group. Although copper is usually preferred, other materials or coated versions thereof are possible as well, in particular coated with supra-conductive material or conductive polymers, such as graphene or poly (3,4-ethylenedioxythiophene) (PEDOT), respectively.

In the context of the present application, the term “electrically insulating layer structure” may denote a layer structure which is electrically non-conductive.

In at least one embodiment, at least one electrically insulating layer structure may comprise at least one of the following group consisting of: a resin or a polymer, such as epoxy resin, cyanate ester resin, benzocyclobutene resin, bismaleimidetriazine resin, polyphenylene derivate (for example based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, for example fibers impregnated with the above-mentioned resins, is called prepreg and may also be used. These prepregs are often named after their properties for example FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating layer structures. It may also comprise at least one of following group of inorganic material: glass, ceramic, quartz,

In the context of the present application, the term “main surface” of a body or a layer structure or a component may particularly denote one of the two largest opposing surfaces of the body or the layer structure or the component or the outermost layers of the component carrier. The main surfaces may be connected by circumferential side walls (“lateral walls”). The thickness of a body, such as component, a stack or sub-stack, or a layer structure may be defined by the distance between the two opposing main surfaces, in particular in direction perpendicular to the extension of the main surface, in particular perpendicular to its planar extension.

In at least one embodiment, at least one lateral wall, preferably the first lateral wall and the second lateral wall, has a plane shape and does in particular not comprise any step or a recess, in particular in a stacking direction. Preferably, at least one lateral wall is formed by a surface extending in parallel to the stacking direction.

In the context of the present application, the term “planarized state” may in particular denote a state of said stack in which said stack has a plane shape, wherein the term “planarized state” may particularly refer to a condition, where a surface or layer is flat or even or has been made flat or even, wherein in an unplanarized state, for example in a mechanically unloaded state, the stack may in particular not have a plane shape. A stack may for example be in a “planarized state” because said stack has been deformed and brought into a plane shape, wherein the deformation may be temporarily or permanently. Such a deformation may for example not only be caused by a mechanical load. In some cases, it may be induced alternatively and/or in addition thermally, i.e., due to heat or cold applied. A stack may for example be in a “planarized state” because of pressure which has been or is being applied to said stack to deform the stack and bring it into the required plane shape. Alternatively, a stack may for example be in an “unplanarized state” under load and in a “planarized state” after release of said load.

In the context of the present application, the term “extension”, in particular with respect to a surface, may particularly denote at least one dimension in space of said surface. An extension may for example be a distance between two defined points, for example between two points on a corresponding surface edge, for example between two points located on opposing surface edges. An extension may be for example a length, in particular an arc length or a straight length between two points along the surface, and/or a maximum height (for example in case of a curved shaped surface, similar to a hill or mountain), wherein an extension in particular may also be defined based on at least one point located outside the respective surface. The term “extension” may in particular encompass an area or volume expansion from an extension of length on the surface height in Z direction (a direction perpendicular to said surface). Preferably, the term “extension” is not limited to only two points on the same surface or opposed surfaces but may in particular also refer to a distance between a lot of points on one line or surface to points on another line or another surface.

In the context of the present application, the term “extension direction” may particularly denote a direction along said extension is defined. An extension direction may be a straight direction, for example an extension extending along or parallel the X-, Y-or Z-axis, and/or a curved direction, as for example a circumferential direction following the outer edge of a circular surface.

In the context of the present application, the term “component” may particularly denote an electronic and/or optical component which is in general configured to be mounted on and/or to be embedded into a component carrier, wherein the component may further in particular be configured to be electrically connected to the component carrier. A component can be an inorganic component (such as, for example, a semiconductor component) or a component comprising inorganic material and/or metal material and/or a combination thereof or consisting thereof. The component may also comprise insulating material

The at least one component may in particular be selected from a group consisting of: an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al2O3) or aluminum nitride (AlN). In order to increase the heat exchange capacity, other geometries with increased surface area are frequently used as well. Further-more, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga2O3), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, in addition or alternatively, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. A component may in general be surface mounted on the component carrier and/or may be embedded in an interior thereof. Moreover, also other components, in particular those which generate and emit electromagnetic radiation and/or are sensitive with regard to electromagnetic radiation propagating from an environment, may be used as component.

In the context of the present application, the term “printed circuit board” (PCB) may particularly denote a component carrier, in particular a plate-shaped component carrier, which is preferably formed by laminating several layer structures, for instance by applying pressure and/or by the supply of thermal energy. A PCB in particular further comprises at least one insulating layer structure.

In at least one embodiment, in particular in a preferred embodiment of a PCB, the PCB is in particular formed by laminating several electrically conductive layer structures with several electrically insulating layer structures. The insulating layer structures may in particular be arranged in between the electrically conductive layer structures, wherein the electrically conductive layer structures and the insulating layer structures may be arranged alternating in a stacking direction.

As preferred materials for PCB technology, the electrically conductive layer structures may be made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole may either connect the whole stack, (through-hole connections extending through several layers or the entire stack), or the filled hole may connect at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board may in particular be configured for accommodating one or more components on one or both opposing main surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier, in particular an IC substrate. An IC substrate may be, in relation to a PCB, a comparably small component carrier onto which one or more components may be mounted and that may act as a connection medium between one or more chip(s) and a further PCB. For instance, an IC substrate may have substantially the same size as a component (in particular an electronic component) to be mounted thereon (for instance in case of a Chip Scale Package (CSP)). More specifically, an IC substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections may in particular be arranged within the IC substrate and may be used to provide electrical, thermal and/or mechanical connections of housed components or unhoused components (such as bare dies), particularly of IC chips, with a printed circuit board or intermediate printed circuit board. A “substrate” in the context of the present application in particular facilitates electrical connections and/or dissipating heat and/or offering mechanical strength. Thus, the term “substrate” is in particular used as a synonym of “IC substrate” in the context of the present application. It has to be noted that the term “substrate” may in particular not been mixed up with the term “substrate” as it is usually used in the wafer context in which “substrate” usually means the substrate material used in wafer manufacturing as a base material upon which devices or circuits are built and which forms the foundational layer that supports the electronic or photonic structures integrated into a wafer. This is not what is meant with “substrate” in the context of the present application.

A dielectric part of a substrate (of an IC substrate) may be composed of resin with reinforcing particles (such as reinforcing spheres, in particular glass spheres).

In the context of the present application, the term “interposer” may in particularly denote a physical structure configured to bridge at least one electrical connection. An interposer may in particular be a physical interface layer structure. An interposer may in particular be configured to spread an electrical connection to a wider pitch and/or to bridge between different connection types. An interposer can be made of various materials, including silicon, glass, or organic substrates. An IC substrate or interposer may in particular comprise or consist of an inorganic layer structure or at least a layer of glass, silicon (Si) and/or a photo-imageable or dry-etchable organic material like epoxy-based build-up material (such as epoxy-based build-up film) or polymer compounds (which may or may not include photo-and/or thermosensitive molecules) like polyimide or polybenzoxazole as electrically insulating material.

In at least one embodiment, the component carrier may further comprise at least one inorganic layer structure, wherein said at least one inorganic layer structure may in particular be part of at least one stack of said component carrier.

In the context of the present application, the term “inorganic layer structure” may particularly denote a layer structure which comprises inorganic material, such as an inorganic compound. In particular, dielectric material of the inorganic layer structure or even the entire inorganic layer structure may be made exclusively or at least substantially exclusively from inorganic material. In another embodiment, the inorganic layer structure may comprise inorganic dielectric material and additionally another dielectric material. An inorganic compound may be a chemical compound that lacks carbon-hydrogen bonds or a chemical compound that is not an organic compound. In an example, the inorganic layer structure may comprise glass, for example silicon base glass, in particular solder lime glass, and/or boro-silicate glass and/or alumo-silicate glass and/or lithium silicate glass and/or alkaline free glass. In another example, the inorganic layer structure may comprise ceramic material, for example aluminum nitride and/or aluminum oxide and/or silicon nitride and/or boron nitride and/or tungsten comprising ceramic material. Yet, in another example, the inorganic layer structure may comprise semi-conducting material, for example silicon and/or germanium and/or silicon oxide and/or germanium oxide and/or silicon carbide and/or gallium nitride. In a further embodiment, the inorganic layer structure may comprise (elemental) metal and/or metal alloys, for example, copper and/or tin and/or bronze. Yet in another embodiment, the inorganic layer structure may comprise inorganic material, which is not listed in the above-mentioned example, such as: MoS2, CuGaO2, AgAlO2, LiGaTe2, AgInSe2, CuFeS2, BeO.

In a planarized state, preferably at least one of said extensions has a planar extension, in particular both the extension of the first main surface and the extension of the second main surface.

In at least one embodiment, said extension of the first main surface may also (i.e., additionally) or alternatively in a non-planarized state of said stack be different from said extension of the second main surface component carrier, i.e., in a state in which at least one of said extensions is in particular not a planar extension.

In at least one embodiment, at least one extension is based on or corresponds to an actual length of the respective main surface of the stack along a planarly and/or linear straight extension direction, wherein at least one extension may, for example extend in a plane perpendicular to the stacking direction. However, an extension of a main surface in the context of the present inventions does not need mandatorily to extend planarly and/or linear straight but may also extend along a curved line and for example define an arc length along a defined path encompassing one, two or three dimensions in space.

If in an unplanarized state a main surface is not planar, in particular not extending in a direction perpendicular to the stacking direction, the resulting and corresponding extension of this main surface may be larger than the direct or shortest distance between the two extremities of said main surface of the respective stack in a defined extension direction along a straight and linear extension direction, extending in a plane perpendicular to the stacking direction. However, if a main surface is planar, at least in a planarized state, then at least in this state the extension and the distance between the main surface extremities correspond one to each other.

If, for example, in an unplanarized state, a main surface has a curved, convex shape, its extension in said unplanarized state may in particular be defined by an arc length of its surface contour. In the unplanarized state the extension defined by the arc length of its surface contour will then be greater than the shortest distance between the outmost extremities of the surface contour. However, in a planarized state the arc length of the planarized surface contour corresponds or is equal to the shortest distance between the outmost extremities of the surface contour. For this reason, preferably the extension of the first main surface and the extension of the second main surface are compared in a planarized state of the component carrier and/or its stack.

For comparison of the extension of the first main surface and the extension of the second main surface, in case the stack is not in a planarized state, the stack may be brought into a planarized state. Therefore, for example, the stack may be placed on a plane ground, preferably with its main surfaces parallel to the ground and/or its stacking direction perpendicular to the ground plane, wherein the edges or lateral walls of said stack are preferably free of any mechanical constraints such that movement of the lateral walls is enabled during the deformation of said stack. Now the stack may for example be pressurized or put under pressure, in particular from above, pressing the stack against the ground plane, until the bottom main surface of said stack (and/or the main surface of the corresponding component carrier comprising said stack) has a plane shape extending parallel to the ground plane and/or contacting said ground plane with substantially the entire bottom main surface. It has to be noted that the extension of the first main surface and the extension of the second main surface may not only been compared in a planarized state. Also, in some cases in an unplanarized state it might be possible to detect, if the extension of the first main surface would be different from an extension of the second main surface in a planarized state of the component carrier. This might in particular be the case, for example, if an arc length of the first main surface is different from an arc length of the second main surface, and when this difference will remain when the component carrier is brought into the planarized state.

In at least one embodiment of a component carrier according to the present invention, at least in a planarized state of said stack, the extension of the first main surface is greater than the extension of the second main surface or vice versa.

By this design in a very easy manner a component carrier may be provided, having a defined and advantageous shape in at least one state and/or being capable of been deformed into a defined and advantageous shape, in particular during or for a step in a further manufacturing process such as assembling with components or other elements, in particular during or for coupling with at least one component, for example an electrical component and/or a heat sink for a accurate reliability and/or function test for component carrier and the final product Therefore the quality and performance of the component carrier and the final product with component can be guaranteed by such structured manufactured by the good control of component carriers' shape.

With this design, in particular very easily a component carrier may be provided having an advantageous shape for further coupling of the component carrier, in particular with a further component, as for example with an electrical component and/or a heat sink. This applies in particular, if the coupling with the further component is performed under at least a small amount of an axial load, in particular under axial pressure, in a stacking direction. The design of a component carrier according to the present invention allows in particular to provide a component carrier with an accurate shape and/or with a shape of a certain flexibility, thus enabling manufacturing of a component carrier within larger tolerance windows. Therefore, a component carrier according to the present invention may help to enlarge the condition windows of manufacturing with good yield and good quality. Subsequently, the following processes for package and/or package test may be more successfully proceeded with lower failure risk. Thereby, finally the quality of the final product as delivered to the end market may be increased.

In at least one embodiment, at least one of said main surfaces of said stack is not planar, wherein in particular both the first main surface and the second main surface are not planar, in particular in at least one state, preferably in an unplanarized state of said stack.

In at least one embodiment, in an unplanarized state, for example in a mechanically unloaded state in which no axial load in a stacking direction is applied to the component carrier and/or its stack, or in a mechanically loaded state in which the component carrier is brought into the unplanarized state by application of an axial load, the first and/or the second main surface and/or the complete stack, may in particular be curved in at least one extension direction, preferably in at least two extension directions.

The stack may for example be formed halfpipe like (curved in one extension direction) or bumpy or bowl-or hill-shaped (curved in two extension directions) in said unplanarized state.

In particular, if the component carrier has for example a convex curved shape on its external side which is facing the heat sink whilst coupling with a further component, very good connection results between the component carrier and the further component can be achieved. Thereby, in particular the contact surface between the component carrier and the further component during coupling can be maximized, which results in advantageous connection properties of the resulting assembly.

In at least one further embodiment, one of the main surfaces, in particular the first main surface or the second main surface, has a concave shape from an external view on the stack, in particular from a top or bottom view on the stack in a stacking direction.

By this design in a very easy manner a component carrier may be provided, having a defined and advantageous shape in at least one state and/or being capable of been deformed into a defined and advantageous shape, in particular during or for a step in a further manufacturing process, in particular during or for coupling with a further component, as for example an electronic component and/or a heat sink.

In at least one embodiment, the other main surface, in particular the second main surface or the first main surface, has a convex shape from a top view on the stack in a stacking direction, preferably in an unplanarized state.

Thereby, very good connection or coupling results between the component carrier and a heat sink can be achieved. This is, because by the axial load applied during connection with a heat sink, the convex curved shaped component carrier may be brought into a planarized state, and therewith, the contact surface between the component carrier and the heat sink during coupling may be maximized, which results in advantageous heat conduction properties of the resulting assembly.

The first and/or the second main surface, and thus in particular said stack, may for example have a convex half-pipe-like shape in a first extension direction and a straight shape in second direction perpendicular to first extension direction.

In an alternative embodiment, the first and/or the second main surface, and thus in particular said stack, for example may have a convex bowl-shape in a first extension direction and also a convex bowl-shape in a second extension direction perpendicular to first extension direction.

In at least one embodiment, at least one lateral wall extends away from at least one of the main surfaces with an internal angle between said lateral wall and the respective or adjacent main surface being different from 90°, i.e., the lateral wall is not perpendicular to at least one of the main surfaces, in particular not exact 90°. However, the internal angle may in be infinitely close to 90°, i.e., a little bigger or smaller than 90°.

In context of the present application the term “internal angle” may in particular denote an angle formed between a lateral wall located and a main surface located adjacent to said lateral wall and intersecting with said lateral wall.

This allows to provide a component carrier with different extensions of the first main surface and the second main surface very easily. This in particular enables providing of a component carrier with different extensions of the first main surface and the second main surface with low effort and allows manufacturing of a component carrier very efficiently and at low costs.

In at least one embodiment, the lateral wall is in particular inclined relative to at least one of the main surfaces with an internal angle between said lateral wall and the respective main surface in the range from 90,001° to 90,05° or 89,95° to 89,999°.

The accuracy of the inner angle allows to benefit at least partly from the benefits of internal angle of exactly 90°, which is in particular advantageous with respect to a warpage control within defined tolerances within the stack (which can be minimized with such an internal angle), but also simultaneous to benefit from a different extension of the first main surface and the second main surface. In other words, i.e., that with an internal angle in the above-described range between 90,001° to 90,05° or 89,95° to 89,999° a good compromise can be achieved. With such good control of the angle, the product quality is guaranteed, and it ensure the following processes can be successfully proceeded and end product has a good quality in the final market.

As already outlined above, in at least one embodiment, in at least one extension direction of said stack an arc length of the first main surface may be different from an arc length of the second main surface in said extension direction, i.e., said extension may be defined by an arc length of the respective surface in the corresponding extension direction.

In the context of the present application the term “arc length” may in particular denote a distance between two points along a section of curve, in the context of the present application in particular along a contour of a main surface along an extension direction.

The arc length of a main surface in an extension direction may in particular be measured between the outmost points of the respective main surface along a surface contour of the corresponding main surface in a planarized state and/or in an unplanarized state, wherein the arc length of a main surface measured in the planarized state is preferably the same as in an unplanarized state of said main surface. Preferably, the outmost points are the respective intersections points of a straight line along the extension direction with the corresponding main surface and the respective lateral wall.

This allows to provide a component carrier with different extensions of the first main surface and the second main surface very easily, wherein the different arc lengths may be provided in the first extension direction or in addition to the different extensions in the first extension direction in a different extension direction.

In at least one embodiment, at least one extension direction may extend in a direction perpendicular to the stacking direction, preferably in a plane perpendicular to said stacking direction.

In a preferred embodiment, the first extension direction may extend in a plane perpendicular to said stacking direction and at least one further extension direction may extend in the same plane with the first extension direction, and perpendicular to said first extension direction. This may in particular apply for different extensions of the first main surface and the second main surface, independently from the character of the extension, i.e., this may apply for straight-line extensions, and as well for arc length extensions.

Different arc lengths may in particular enable providing of a component carrier with different extensions of the first main surface and the second main surface with low effort and allows manufacturing of a component carrier very efficiently and at low costs. With such kind of structure/shape and flexibility of structure/shape change by the invention, the component carrier does not only meet the requirements of final package manufacturing and manufacturing of a component carrier, but also provide a big advantage for accurate results in burn in tests and low failure risks in burn in tests.

In at least one embodiment, a first extension in a first extension direction of the first main surface is different from an extension of the second main surface in said first extension direction, and wherein a second extension in a second extension direction of the first main surface is different from a second extension of the second main surface in said second extension direction, wherein the second extension direction is different from the first extension direction, in particular extending in a common plane with the first extension direction and preferably perpendicular to said first extension direction.

This allows to provide a stack respectively a component carrier comprising such a stack with advantageous extensions of the first and the second main surfaces. This allows to provide a very advantageous component carrier requiring low effort which can manufactured efficiently and at low costs. Additionally, such a component carrier may be able to cover the issues from the shrinkage of layer structure in the whole manufacturing process of the component carrier and to control the warpage at a level which does not impact the function and quality of the component carrier.

In at least one embodiment, in particular a first arc length in a first extension direction of the first main surface is different from a first arc length of the second main surface in said first extension direction. Preferably, a second arc length in a second extension direction of the first main surface is different from a second arc length of the second main surface in said second extension direction, wherein the second extension direction is different from the first extension direction, in particular extending in a common plane with the first extension direction and preferably perpendicular to said first extension direction.

This allows to provide a stack respectively a component carrier comprising such a stack with very advantageous extensions of the first and the second main surfaces. This allows to provide a very advantageous component carrier requiring low effort which can manufactured efficiently and at low costs.

In at least one embodiment, in at least one extension direction of the main surfaces an extension difference between an extension of the first main surface and an extension of the second main surface in said extension direction is in a range from 0.02 μm, 0.05 μm or 0.1 μm up to 0.2 μm, 0.3 μm or 0.5 μm, wherein the arc length difference is in particular in a range from 0.02-0.5 μm or 0.05-0.3 μm, preferably in a range of 0.1-0.2 μm.

In at least one embodiment, in particular in at least one extension direction of the main surfaces an arc length difference between an arc length of the first main surface and an arc length of the second main surface in said extension direction may be in a range from 0.02 μm, 0.05 μm or 0.1 μm up to 0.2 μm, 0.3 μm or 0.5 μm, wherein the arc length difference is in particular in a range from 0.02-0.5 μm or 0.05-0.3 μm, preferably in a range of 0.1-0.2 μm.

In particular an arc length difference between the first arc lengths of the first and second main surfaces in the first extension direction and/or between the second arc lengths of the first and second main surfaces in the second extension direction may be in this range.

Thereby, very good connection or coupling results between the component carrier and a further component can be achieved with the above-mentioned advantages.

In at least one embodiment, a first extension difference in a first extension direction is different from a second extension difference in a second extension direction, wherein the second extension direction is different from the first extension direction.

Thereby, very good connection or coupling results between the component carrier and a further component can be achieved,

This allows to provide a component carrier with different extensions of the first main surface and the second main surface very easily. This in particular enables providing of a component carrier with different extensions of the first main surface and the second main surface with low effort and allows manufacturing of a component carrier very efficiently and at low costs.

In at least one embodiment, the second extension direction may in particular extend perpendicular to the first extension direction, but preferably in the same plane. This applies not only for the feature combination described directly above, but in general also for the other feature combinations described herein, because this allows to provide a component carrier which may be adapted flexible and in detail to different requirements.

In at least one embodiment, at least one extension difference is equally distributed along the respective extension direction, in particular with an equal, i.e., symmetrically, overhang of the main surface having the larger extension on both sides.

This allows to provide a component carrier having symmetric properties at least in the respective extension direction. This may also help to reduce residual stresses in turn in the stack and to provide a stack with in particular advantageous mechanical behavior.

In at least one embodiment, at least one of the main surfaces comprises one or more connection surfaces being configured for establishing an electrical connection with at least one external component, in particular with at least one electrical external component.

This allows to provide a component carrier which is enabled to be electrically connected with at least one external component via at least one main surface, in particular with at least one electrical external component, and this very easily, because at least some means being necessary for electrical connection are already provided.

In the context of the present application the term “connection surface” may particularly denote a surface which is being configured to establish at least one electrical connection with at least one electrical component. Such a connection surface may include any kind of structure configured to establish an electric connection as for example described herein in the context of an electrically conductive layer structure. The connection surface may comprise an interface or a boundary region between the component and component carrier. A connection surface may in particular provide a compact connection within the/of two elements.

In at least one embodiment, at least one main surface comprising at least one connection surface may have a concave shape, wherein the other main surface may in particular have a convex shape, in particular with respect to two different and opposing points of view from outside from the stack, in particular with respect to a first point of view for looking in a direction perpendicular to said stack from outside of the stack onto the first main surface facing said first point of view, and a second point of view for looking in the direction perpendicular to said stack from outside of the stack onto the second main surface facing said second point of view.

For example, the first main surface may have a concave shape, and the second main surface may have a convex shape with respect to two different and opposing points of view from outside from the stack. When looking from the same point of view, both main surfaces may have the same shape and be formed for example both convex or both concave, wherein the first main surface and the second main surface may in particular have almost parallel or exact parallel surface contours but only different extensions in at least one extension direction at least in a planarized state.

Thereby, very good connections may result between the component carrier and a further component. Such a component carrier may in particular flexibly allow to enable the establishment of compact connections at two sides of the component carrier with other elements based on a final application.

In at least one embodiment, at least one main surface comprising at least one connection surface has a convex shape, wherein the other main surface has in particular a concave shape.

For example, the first main surface may have a convex shape, and the second main surface may have a concave shape with respect to two different and opposing points of view from outside from the stack. When looking from the same point of view, both main surfaces may have the same shape and be formed for example both convex or both concave, wherein the first main surface and the second main surface may in particular have almost parallel or exact parallel surface contours but only different extensions in at least one extension direction at least in a planarized state.

Thereby, very good connections may result between the component carrier and a further component. Such a component carrier may in particular flexibly allow to enable the establishment of compact connections at two sides of the component carrier with other elements based on a final application.

In at least one embodiment, the other main surface also comprises one or more connection surfaces.

This allows to provide a component carrier being configured to establish electrical connections from both sides. This increases the number of possible use cases for a specific component carrier and increases its flexibility for use. Due to the higher amount of use cases, more component carriers may be sold with the same design which will result in lower costs per component carrier because the R&D costs can be allocated to a larger number of component carriers. With such a structure or shape, the component carrier may allow realization of a high density of connections with good quality, so it may become applicable for high performance computing.

In at least one embodiment, at least one connection surface comprises one or more solder balls and/or pillars being electrical connected to said respective connection surface.

Thereby, very easy and reliable electrical connections with other electrical components can be established.

In at least one embodiment, at least one main surface comprising at least one connection surface comprising one or more solder balls and/or pillars being electrical connected to said respective connection surface has a concave shape, wherein the other main surface has in particular a convex shape, in particular with respect to two different and opposing points of view from outside from the stack. When looking from the same point of view, both main surfaces may have the same shape and be formed for example both convex or both concave, wherein the first main surface and the second main surface may in particular have almost parallel or exact parallel surface contours but only different extensions in at least one extension direction at least in a planarized state.

Thereby, very good connection results between the component carrier and a heat sink can be achieved. And the control of the shape adaption for the component carrier may provide a benefit for the uniformity of solder balls and/or pillars, so the connections may be (more) reliable.

In at least one embodiment, at least one main surface comprising at least one connection surface comprising one or more solder balls and/or pillars being electrical connected to said respective connection surface has a convex shape, wherein the other main surface has in particular a concave shape, in particular with respect to two different and opposing points of view from outside from the stack.

Thereby, very good connections may result between the component carrier and a further component. Such a component carrier may in particular flexibly allow to enable the establishment of compact connections at two sides of the component carrier with other elements based on a final application.

A method according to the second aspect of the invention for manufacturing a component carrier, is in particular for manufacturing of a component carrier according to the first aspect of the invention wherein the method at least comprises the following step:
providing at least one stack having a stacking direction, wherein said stack comprises at least one electrically conductive layer structure, at least one electrically insulating structure, a first main surface and a second main surface, wherein said first main surface and said second main surface are provided one above the other in a stacking direction and being opposed one to each other, and wherein a first lateral wall and a second lateral wall between said first and second main surfaces connecting said opposed main surfaces. The component carrier, in particular the stack, is designed such that at least in a planarized state of said stack an extension of the first main surface is different from an extension of the second main surface.

In at least one implementation and/or one embodiment, the method may in particular comprise at least a step b) providing a component carrier with said stack.

By a method according to the second aspect of the present invention in a very easy and efficient manner and advantageous component carrier may be provided, in particular a component carrier having a defined and advantageous shape in at least one state and/or being capable of being deformed into a defined and advantageous shape as described above with respect to the component carrier.

This method in particular allows to provide, in particular in an advantageous manner, an advantageously shaped component carrier and/or a component carrier being deformable into an advantageous shape, in particular into a concave or convex shape, which is a very advantageous shape for the above described reasons. This method is further very flexible in the component carrier manufacturing to achieve any shape based on the requirements and final applications.

In at least embodiment, the step of providing of said stack at least includes:
providing a panel comprising a panel stack comprising at least one electrically conductive layer structure and at least one electrically insulating layer structure, said layer structures being configured to be divided in a plurality of component carrier stacks;
deforming the panel along the respective thickness direction changing the planar shape of at least one main surface of said panel, in particular into a curved shape, preferably into a concave shape with respect to a top view in a direction perpendicular to the stacking direction; and
separating the deformed panel into sub-panels or single stacks, in particular by dicing.

In the context of the present application the term “panel stack” may in particular denote an array of stacks, preferably of similarly or identically shaped stacks. A panel stack may in particular comprise a repetition of similar or identical-shaped electrically conductive layer portions and electrically insulating layer portions along a planar panel extension, in particular at the same thickness and/or stack position, eventually along an array distribution, so that after the separation of the panel stack in sub-panels or a plurality of component carrier stacks the divided portion(s) may be used for further processing to manufacture one or more component carrier according to the first aspect of the present invention.

In the context of the present application, the term “sub-panel” may in particular denote a sub-array of component carrier stacks to be subsequently singularized (it can be common for some products), fourth further processing to manufacture one or more component carrier according to the first aspect of the present invention. The sub-panel can be a half panel or quarter panel or any other unit of a panel.

Deformation of the panel along the respective thickness direction and thereby changing the planar shape of at least one more main surface of said panel, in particular into a curved shape, preferably into a concave shape with respect to top view in a direction perpendicular to the stacking direction, preferably for and during separation, may reliably result in a component carrier having an advantageous shape for coupling with a heat sink such that advantages good heat conductivity may be achieved. Due to the property of material used in the component carrier, especially the insulating material, and the process with a lot of thermal treatments until the singulation, the component carrier usually undergoes shrinkage and warpage. With such kind of situation, a common component carrier as known from prior art might have big risk for failure of an electrical connection with another element. However, by using the method according to the present invention for manufacturing a component carrier, the shrinkage and warpage can be compensated to mitigate the connection failure risk.

In at least embodiment, the panel is deformed such that it has at least partially, preferably over its total extension, a curved shape.

Thereby, in a very reliable and easy manner, a component carrier having an advantageous shape for coupling with a heat sink can be provided.

In at least embodiment, whilst the deformed panel is separated, it is being hold on a supporting structure, in particular by at least using a vacuum and or applying negative pressure.

Thereby, in a very easy manner the deformation of the panel may be caused, and this in particular very reproducible and within a small tolerance window of geometric deviations.

The supporting structure used is preferably designed accordingly in particular for enabling the wanted deformation, in particular for deforming the panel into a curved shape, preferably by vacuum or by applying negative (air) pressure (suction).

In the context of the present application the term “supporting structure” may in particular denote any mechanical holding structure, for example a rack or the like, which is configured to support the panel during separation without damaging.

In the context of the present application, the term “vacuum” may particularly denote a technology or system that uses negative pressure, in particular negative air pressure and/or suction to handle, move, or hold and/or suck any component carrier securely during various stages of the manufacturing process of the component carrier, wherein the negative pressure is in particular of an amount being sufficient for the respective task. With using vacuum and/or pressure, the shape of the component carrier may in particular flexibly be changed while singulation, based on the respective requirements and/or the final application.

In at least embodiment, wherein the panel comprises at least one connection surface and is hold on said supporting structure whilst separation such that said connection surface is facing away from said supporting structure, wherein said at least one connection surface in particular comprises solder balls and/or pillars (on the side facing away from the supporting structure).

In at least one embodiment, therein the vacuum is in particular applied onto the surface side of the supporting structure which may in particular be opposed to said connection surface.

Thereby, in a very easy manner, a component carrier having an advantageous shape for coupling with a further component for the reasons described above.

In some embodiments, this has further the advantage that the panel to be separated has not been flipped or turned by 180° before separation, what means that a process step may be omitted resulting in increased process efficiency and lower manufacturing costs.

In at least embodiment, wherein the panel is hold on said supporting structure whilst separation such that it has a bowl-shape with the opening of said “bowl” facing away from said supporting structure.

In the context of the present application the term “bowl-shape” or “bowl-shaped” may particularly denote a substantially round or circular or elliptic hollow form with at least one concave surface that in particular resembles the shape of a common kitchen wall looks similar to such a kitchen bowl. The bowl shape can denote a warpage of the component carrier.

Due to the material property of component carrier and manufacturing process, the warpage of the component carrier cannot be totally eliminated, therefore controlling of the warpage level becomes significantly important to ensure the quality and electrical performance of the component carrier. By deforming the panel into a bowl-shape, in a very easy manner, a component carrier having an advantageous shape for coupling with the heat sink to enable advantageous good heat conductivity of the resulting assembly may be provided. The quality and the reliability of product can be guaranteed at least in some embodiments.

A package according to the third aspect of the present invention comprises at least one component carrier according to the first aspect of the present invention and/or at least one component carrier manufactured by a method according to the second aspect of the invention, and a least one further part being assembled with the component carrier.

In the context of the present application, the term “package” may particularly denote a setup or unit that integrates a component carrier and at least one further part.

In the context of the present application, the term “further part” may particularly denote any part which is being configured for forming a package together with at least one component carrier. This may include other hardware, software, or mechanical parts to form a functional package or assembly or device or a module of a larger system.

In at least one embodiment, the package is an electronic package or assembly. The package may comprise at least one electronic component.

A package may be, for example, an electronic circuit board comprising at least one component carrier according to the present invention and at least one further part, wherein one or more further parts may be formed by parts and/or components being electrically connected (to each other and/or with the component carrier).

A package may be, for example, an electronic module, an electronic device or any sub-assembly for an electronic device, comprising at least one component carrier according to the present invention and at least one further part.

In at least one embodiment, a package may further comprise at least on component being assembled and/or mounted on one of the main surfaces of the component carrier, wherein the package may preferably further comprise at least one further component carrier. Said further component carrier may also be a component carrier according to the present invention or a different one, in particular a conventional one, as for example be known from prior art. The further component carrier may in particular be or comprise a PCB, more in particular a motherboard, wherein the further component carrier is preferably arranged on the other one of the main surfaces of said component carrier, wherein the further component carrier may in particular be connected (thermally and/or electrically) with said component carrier. In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

In at least one embodiment, a component carrier according to the first aspect of the invention, in particular at least one stack of the component carrier, may further comprise a solder resist layer structure and/or a protective layer structure, wherein the protective layer structure may in particular be applied at least partly to at least a part of the electrically conductive layer structure.

In the context of the present application, the term “solder resist layer structure” may particularly denote a layer structure which may also be named as “solder mask” and which may in particular be applied to a surface of another layer structure, in particular to a main surface of said other layer structure, to prevent solder from adhering to unintended areas of said surface of said other layer structure during the soldering process. Thus, ensuring that solder is applied only to designated areas, as for example to designated solder pads, but not on the spaces in between these designated areas.

In at least one embodiment, the solder resist layer structure may be an electrically insulating solder resist layer structure. In at least one embodiment, the solder resist layer structure may be applied to a main surface of an electrically conductive layer structure, wherein the solder resist layer structure may in particular be applied to the outmost main surface of the at least one electrically conductive layer structure of a component carrier. The solder resist layers structure may be applied to one or both opposing main surfaces of a layer structure or a stack, wherein the solder resist layer structure may in particular be applied to the outmost main surfaces of the layer structure or the stack. The solder resist layer structure may be applied in terms of or by surface treatment. The solder resist layer structure may also act as a permanent protective layer to protect the circuit pattern from dust, heat, and moisture as well as insulating the component carrier's circuitry. The solder resist layer structure may also protect from mechanical influences, for example scratches.

In at least on embodiment, the solder resist layer structure may be formed by applying the solder resist layer structure onto an entire main surface of a layer structure to be covered first, and then subsequently pattern the solder resist layer structure so as to expose one or more surface portions of the layer structure coated by the solder resist layer structure before. The solder resist layer structure may in particular be applied onto an entire main surface of an outmost electrically conductive layer structure of a component carrier first, and then subsequently be patterned so as to expose one or more electrically conductive surface portions of the electrically conductive layer structure coated by the solder resist layer structure before. Thereby, at least one opening in the solder resist layer structure may be formed, wherein at least one opening may be delimited by at least one lateral wall of said solder resist layer structure, wherein at least one lateral wall particularly limits the opening in a lateral or transversal direction to the stacking direction.

In the context of the present application, the term “protective layer structure” may in particular denote a layer structure which can be considered as a “surface finish layer structure” and which is in particular configured to prevent a surface, to which the protective layer structure has been applied to, from changing one or more of its characteristic properties within a defined timeframe under defined conditions.

A protective layer structure may in particular be, for example, a layer structure which may be applied to at least one exposed portion of an electrically conductive layer structure for the time being until an electric connection is established between the exposed portion and, for example, an electronic periphery. If an exposed surface portion of an electrically conductive layer structure is left unprotected, then the exposed electrically conductive layer structure material (in particular copper) might oxidize. This may result in a change of one or more characteristic properties of the electrically conductive layer structure in the zone of the exposed surface portion and making a component carrier with such an electrically conductive layer structure less reliable.

The protective layer structure has the function to protect the exposed electrically conductive layer structure (in particular copper circuitry) and enable a joining process, in particular reliable electrical connection process, with one or more components, for instance by soldering.

In at least one embodiment, at least one protective layer structure may be applied selectively to one or more exposed electrically conductive surface portions of an electrically conductive layer structure of the component carrier in terms of or by surface treatment.

A protective layer structure may comprise or be an electrically conductive cover material configured to be applied on exposed electrically conductive layer structures (such as pads, conductive tracks, etc., in particular comprising or consisting of copper) of a surface, in particular of an outmost and electrically conductive main surface of a component carrier. Examples for appropriate materials for protective layer structure material are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

A protective layer structure may be formed for instance as an interface or to act as an interface between a surface mounted component and the component carrier.

Examples for electronic devices are smartphones, computers and laptops, televisions and monitors, wearable devices (like, e.g., smartwatches and/or fitness trackers), home devices (such as, e.g., microwave ovens, refrigerators, and washing machines), medical devices (like, e.g., blood glucose meters and portable ultrasound machines), electronic devices for the automotive industry (like, e.g., ECUs for engine management, infotainment systems, safety systems (like, e.g., airbags), and navigation systems), electronic devices for industrial machinery (like, e.g., control units for automation, robotics, and manufacturing equipment).

Examples for sub-assemblies for electronic devices are in particular electronic modules for the electronic devices mentioned above. Examples for modules are in particular electronic control units (ECUs), power supply modules, connectivity or communication modules (like, e.g., HDMI or USB ports, WiFi modules, Bluetooth modules and GSP modules), sensor modules (e.g., heart rate, GPS), microcontroller modules, battery management modules, display interface modules, driver modules, audio modules, RFID modules, and memory modules.

The preferred embodiments presented with reference to a component carrier and its advantages apply correspondingly to a method according to the second aspect of the invention for manufacturing a component carrier according to invention, and to a package according to the third aspect of the invention as well and vice versa.

Further features of the invention are shown in the claims, the figures, and the description of the figures. All the features and combinations of features mentioned above in the description as well as the features and combinations of features mentioned below in the description of the figures and/or shown alone or in combination in the figures can be used not only in the combination as indicated or shown in each case, but also in other combinations or on their own so far it can technically be realized.

### SHORT DESCRIPTION OF THE DRAWINGS

The aspects of the present invention defined above, and further aspects of the invention are apparent from the examples will now be explained in more detail by means of a preferred embodiment example and with reference to the accompanying, but not limiting drawings.

The drawings show:

FIG. 1: a schematic illustration of a cross-section through an exemplary UBI-test (Unit Burn In-test) configuration for testing reliability and quality of a component carrier by thermal test as it is known from prior art,

FIG. 2: a schematic cross-section of a first example of an embodiment of a component carrier according to the present invention in a planarized state,

FIG. 3: a schematic cross-section of the component carrier of FIG. 2 in an unplanarized state,

FIG. 4: a schematic illustration of a snapshot of a panel before separation during manufacturing of a component carrier by using a first example of a method according to the present invention, wherein the panel comprises several panel stacks,

FIG. 5: a schematic illustration of a cross-section through the panel of FIG. 4 respectively of one of its panel stacks after separation, but with the separated panel stack (the resulting component carrier) still hold on the used supporting structure,

FIG. 6: an enlarged view of the right area of the separated panel stack (the resulting component carrier) of FIG. 5, and

FIG. 7: a flow chart of an exemplary embodiment of a method for manufacturing a component carrier according to the present invention.

### DETAILED DESCRIPTION OF EXEMPLARY EMBODIMENTS

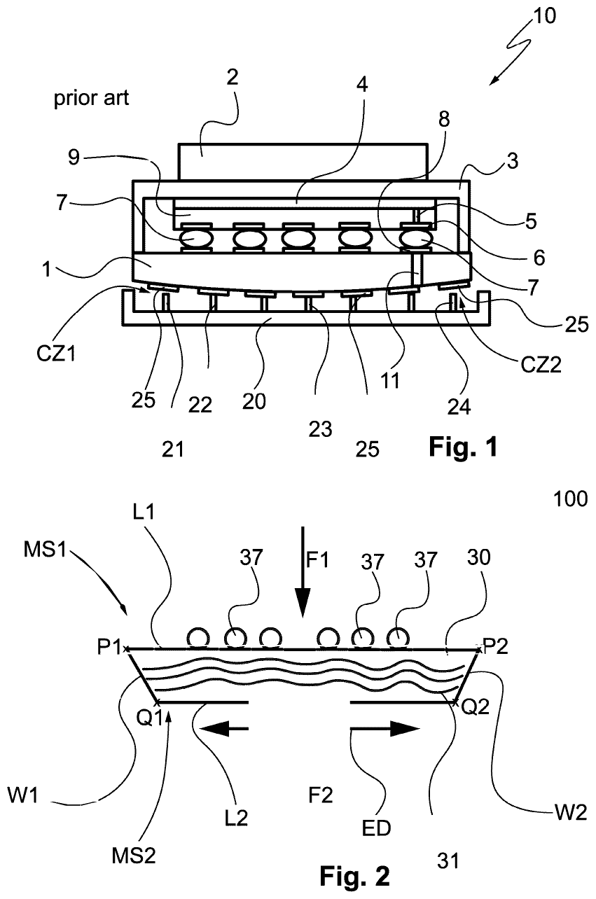

FIG. 1 shows a schematic illustration of a cross-section through an exemplary UBI-test (Unit Burn In-test) configuration 10 for testing reliability and quality by applying heat of a component carrier 1 as it is known from prior art.

For performing such an UBI-test the component carrier 1 is fixed between a lower thermistor 20 and an upper thermistor 9 and electrically and thermally connected to said thermistors 20 and 9, wherein the upper thermistor 9 is mounted onto a die 4 which is thermally connected to a specific UBI heater 2, by which defined heat can be applied to the component carrier 1 via the upper thermistor 9.

Over established electrical connections between the UBI heater 2, the die 4, conductive structures 5, the upper thermistor 9, and via heater contacts 6 and electrically conductive structures 7, which may for example be solder balls 7 or the like as in this example, and upper electrical contacts 8 of the component carrier 1, heat from the UBI heater 2 can be introduced into the component carrier 1.

Over at least one electrically conductive structure 11 within the component carrier 1, which is as illustrated in this example as a through connection, in particular as a vias, the thermal heat generated by the UBI heater 2 can be introduced into the component carrier 1, and from there through the component carrier 1 further to the bottom surface of the component carrier 1 into lower contacts of 25 of the component carrier 1.

In the UBI test configuration illustrated in FIG. 1, the lower contacts 25 of the component carrier 1 are configured to be connected inter alia with the detection contacts 21, 22, 23 and 24 of the lower thermistor 20, wherein the lower thermistor 20 acts as a heat sink. To measure the reliability and quality of the component carrier 1 by applying heat, in particular its ability to dissipate heat, a lower thermistor 20 is provided. The higher the amount of heat is, which is detected by the lower thermistor 20, the higher the ability of heat conductivity of the component carrier 1 is and the more accuracy of the test result will be achieved and the less failure will be seen for component carrier 1, resulting in a lower thermal load of the components being encompassed, in particular embedded in said component carrier 1.

Therein, the capability of heat conductivity of the component carrier 1 does not only depend on the component carrier 1 itself, but also on the quality which can be achieved when connecting the component carrier 1 with external parts, e.g., with a heat sink.

With a test configuration as illustrated in FIG. 1, the ability of the component carrier 1 for heat conductivity can be examined. Therefore, a defined heat is applied with the UBI heater 2, and in particular introduced or guided into the component carrier 1, wherein the introduced amount of heat may in particular be detected by the upper thermistor 9. By the lower thermistor 20 the heat delivered from the component carrier 1 can be detected and analyzed, wherein it is in particular checked, if the component carrier 1 fulfills the requirements for heat conductivity it should fulfill. Thermistors 9 and 20 are preferably components having an electrical resistance changing significantly with temperature what enables easy measurement of the function or reliability of product by heat conductivity of a component carrier 1.

UBI tests (UBT) are well-known from prior art for which is referred to herewith with respect to UBT in general.

The better the quality of the established electrical and terminally conductive connections is, the higher the amount of heat transferred or introduced into the lower thermistor 20 will be, and vice versa.

Bad established connections or no connections as exemplarily illustrated in FIG. 1 in contact zones CZ1 and CZ2 between lower contacts 25 of the component carrier 1 and detection contacts 21 and 24 of the lower thermistor 20, will result in insufficient heat conductivity or delivery and result in test failure of the UBI test of component carrier 1.

As it is apparent from FIG. 1, the bad connections in connection or contact zones CZ1 and CZ2 are caused by the shape of the bottom main surface of the component carrier 1, which is in this example convex shaped with respect to a view from the bottom side in a direction perpendicular to the bottom surface of said component carrier 1.

With a component carrier 100 according to the present invention, the risk of contact issues like this and therewith the risk of electrical connection failure between the component carrier and components and the risk of test failure in the UBI test, may significantly be reduced and in some cases even avoided.

FIG. 2 shows a schematic cross-section of a first example of an embodiment of a component carrier 100 according to the present invention, wherein said component carrier 100 is illustrated in a planarized state in FIG. 2.

Said component carrier 100 comprises a stack 30 with a stacking direction (not indicated with a reference sign herein), wherein said stack comprises a plurality of layers 31, in particular at least one electrically conductive layer (not explicitly illustrated), and at least one electrically insulation layer structure (also not explicitly illustrated). The component carrier 100 further comprises a first main surface MS1 and a second main surface MS2. Said first main surface MS1 and said second main surface MS2 are provided one above the other in a stacking direction and being opposed one to each other. The component carrier 100 further comprises a first lateral wall W1 and a second lateral wall W2 between said first and second main surfaces MS1, MS2, connecting said opposed main surfaces MS1 and MS2.

For establishing at least one connection of said component carrier 100 with an external component, in particular for establishing at least one electrical connection with an external component, the first main surface MS1 is configured as a connection surface and comprises several solder balls 37 forming electrically conductive structures 37. The component carrier 100, in particular its first main surface MS1, may in particular form a high density array or pitch for mounting one or more complex components like active dies, in particular processor or memory chips onto said main surface.

In this illustrated planarized state an extension of the first main surface MS1, in this example in particular a length L1, is different from an extension to of the second main surface MS2, in particular of a length L2, in an extension direction ED. In this embodiment, the extensions are lengths L1, L2 and the extension direction ED is extending perpendicular to the stacking direction.

The second main surface MS2 may in particular comprise one or more connection structures (not shown) for connecting the component carrier 100 to a further component carrier, e.g., a PCB. Those connection structures (of the second main surface MS2) may preferably have a connection density lower than the connection density of the first main surface MS1 and are preferably larger in their dimensions than those of the first main surface MS1—and in case of a solder connection, the solder balls of the second main surface MS2 may in particular also be larger than those of the first main surface MS1.

In other embodiments the extension direction may extend in a different direction, for example in a direction perpendicular to the extension direction ED, but preferably also in a plane perpendicular to the stacking direction. But this is not mandatory. The extensions also do not need to be straight lengths. Also, an arc length of a main surface may define an extension.

In other embodiments, the extensions of the first main surface and the second main surface may differ in more than one extension direction, wherein the extension difference may be different for the different extension directions.

In the embodiment illustrated in FIG. 2, the length L1 is defined by the shortest distance between the first outmost point P1 and the second outmost point P2 of the first main surface MS1 in the planarized state, and the length L2 is defined by the shortest distance between the first outmost point Q1 and the second outmost point Q2 of the second main surface MS2 in the planarized state.

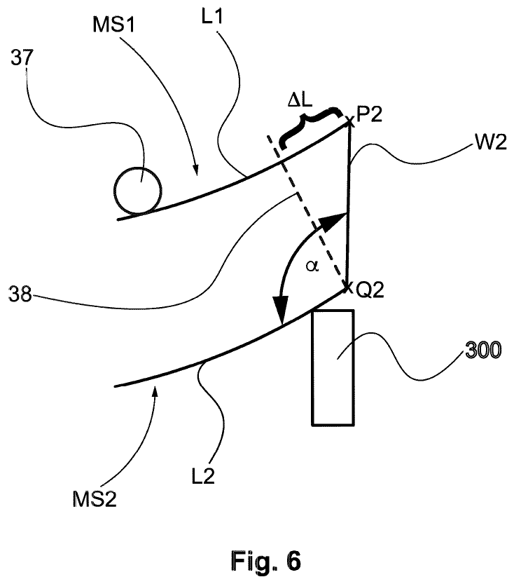

In this embodiment, length L1 is larger than length L2, i.e., in particular the extension of the main surface MS1 being configured as connection surface and comprising the solder balls 37, wherein the extension difference, i.e., the length difference L1−L2=2ΔL, is equally distributed over an extension direction ED to both sides (left and right side) of the first main surface MS1. That means, half ΔL of the overall length difference 2ΔL, as illustrated exemplarily in FIG. 6, is the same on both sides of the lateral walls W1 and W2. In other embodiments, this might also be different.

Due to the different lengths L1 and L2, wherein the length L1 of the first main surface MS1 is larger than the length L2 of the second main surface MS2, in extension direction ED. Lateral walls W1 and W2 extend not perpendicular to the main surfaces MS1, MS2, but with an angle α being different from 90°, as it is schematically illustrated in FIG. 2 and exemplarily in detail in FIG. 6.

The component carrier 100 may be configured such that it will adopt the planarized state when being mechanically unloaded, i.e., when not subjected to a mechanical load F1 and/or F2 as exemplarily illustrated in FIG. 2, or such that it will only adopt the planarized state when be subjected to a defined mechanically load, in particular a defined axial load in a stacking direction, wherein the last variant is in particular preferred.

In case the component carrier 100 is configured such that it will adopt the planarized state only when being subjected to an axial load in a stacking direction, the component carrier 100 may be brought into said planarized state, for example, by applying an axial pressure force F1 resulting in a positive pressure and/or by applying an axial tensile force or suction force F2 resulting in a negative pressure to the bottom side (to the second main surface MS2) of said component carrier 100.

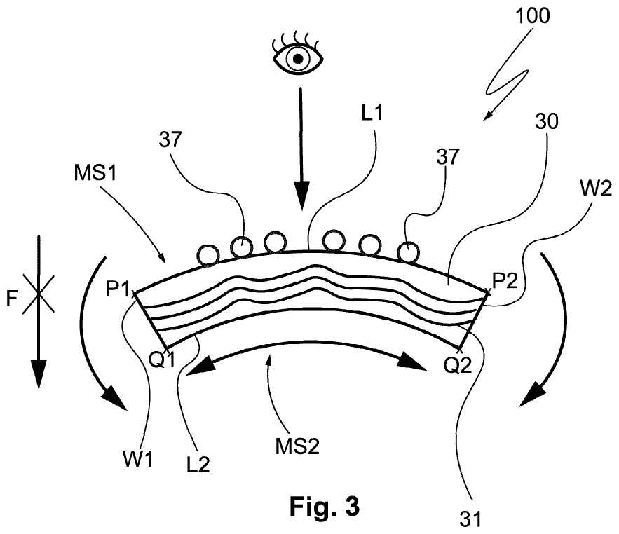

FIG. 3 shows a schematic cross-section of the component carrier 100 of FIG. 2 in an unplanarized state, wherein in this illustration of component carrier 100 an applied force F1 respectively F2 as symbolically illustrated in FIG. 2 has been released, resulting in the deformation of the component carrier 100 into a convex shape (symbolically illustrated by the curved arrows) with respect to a top view from above in a direction perpendicular to the first main surface MS1 onto said first main surface MS1 symbolically illustrated by an eye.

In this unplanarized state of the component carrier 100, the first main surface MS1, on which the electrically conductive structures 37, in this example solder balls 37, are provided, has a convex shape, with respect to a top view from above, wherein the bottom surface, in this case the second main surface MS2, has a concave shape with respect to a bottom view from below in a direction perpendicular to said second main surface MS2, resulting in almost parallel main surfaces MS1 and MS2.

As it becomes apparent from FIG. 3, the extension difference 2ΔL=L1−L2 of the main surfaces MS1 and MS2 does not only exist in a planarized state. In this embodiment, it also exists in an unplanarized state, wherein in particular an extension difference between the arc lengths L1 of a surface contour of the first main surface MS1 and the arc length L2 of the surface contour of the second main surface MS2 exists. Such a configuration may also lead to the desired result of a component carrier 100 according to the present invention. Also, in this embodiment and as illustrated in FIGS. 2 and 6, the lateral walls W1 and W2 may in particular extend with an inner angle α being different from 90° to the adjacent main surface(s) MS1, MS2, although it is almost not apparent from FIG. 3 due the low deviation from 90°.

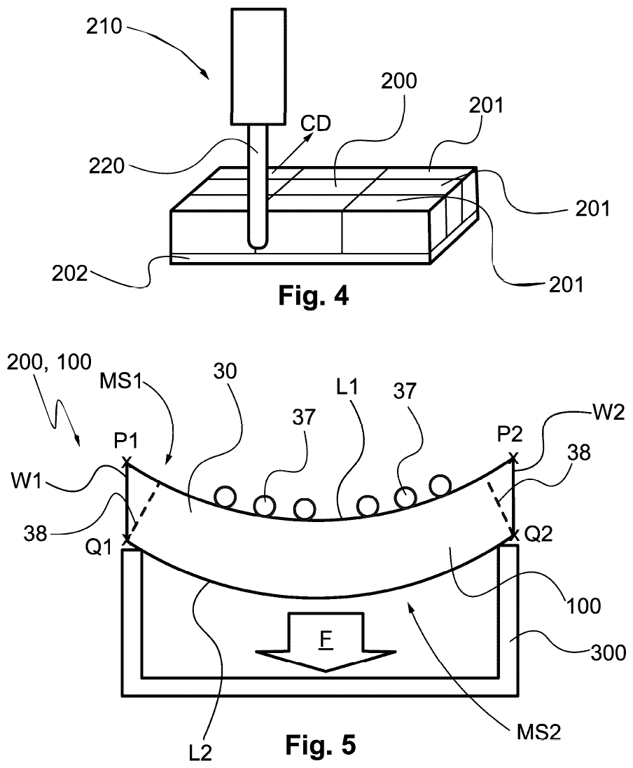

FIG. 4 shows a schematic illustration of a snapshot of a panel 200 comprising a panel stack being configured to be separated into several similarly configured component carrier stacks 201, which are mounted on a panel carrier 202. Said panel 200 is shown during manufacturing of a component carrier 100 by using a first example of a method according to the present invention, wherein the snapshot relates to a state before separation by dicing by laser grooving. Said panel 200 may be separated by separation means 210, for example by separation means 210 for performing laser grooving or mechanical cutting by drilling. Separation may, for example, be done by cutting the panel using a laser beam 220 and moving said laser beam 220 in at least one (separation, in particular cutting) direction. Exemplarily, only a first cutting direction CD is illustrated. In addition, one or more separation steps may be required to separate the panel. Therefore, the separation means 210 (here the laser beam 220) may be moved along at least one other separation direction, for example along a second cutting direction (not shown) extending perpendicular to the illustrated cutting direction CD. During separation said panel 200 may be hold by a supporting structure 300 (see FIG. 5) by negative pressure F, in particular by a vacuum, wherein the supporting structure 300 may for example be a suction table 300 or the like.

FIG. 5 shows a schematic illustration of a cross-section through the panel 200 of FIG. 4 respectively of one of its component carrier stacks 201 after separation by dicing, in particular by laser grooving, but with the separated component carrier stack 201 (respectively the resulting component carrier 100) still being hold on the used supporting structure 300.

In a preferred method according to the present invention for manufacturing a component carrier 100 according to the present invention, the panel 200 is preferably hold such on said supporting structure 300, that the panel 200 is in particular deformed in its thickness direction (in a stacking direction) such that a planar shape of the panel 200 is changed into a concave shape as illustrated in FIG. 5.

Preferably, during the separation step, in particular when the separation is done by dicing, in particular by laser grooving or mechanically drilling or cutting, the panel 200 is hold such on said supporting structure 300 that the connection surface comprising the solder balls 37 is facing away from the supporting structure 300, i.e., facing away from the suction side.

The amount of suction force F is in particular adjusted such that the panel is deformed into the concave shape as described above and as illustrated in FIG. 5, but preferably without causing any damage of the panel 200.

Thereby, in particular by holding the panel 200 like illustrated in FIG. 5 during separation, in a very easy manner, in particular by only cutting the panel 200 vertically, the different extensions L1 and L2 of the first main surface MS1 and the second main surface MS2 can be provided, what becomes clear when looking at the dotted lines 38 in FIG. 5, which mark the lines for constant lengths/extension (in theory) of the first main surface MS1 and the second main surface MS2.

Separating said panel 200 into component carrier stacks 201 with an arrangement as illustrated in FIG. 5, with the conductive structures 37 side up (on the upper surface), will except for some component carriers 100 due to manufacturing tolerances lead to component carriers 100 as illustrated in FIG. 2 (when planarized) respectively to component carriers 100 as illustrated in FIG. 3 (when in an unplanarized state respectively when the suction force F is fully or completely released and in particular no other force is applied to planarize the component carrier 100).

Arranging a component carrier 100 according to the present invention in the UBI test configuration as illustrated in FIG. 1, in which the component carrier 100 will get planarized, will also not only cause planarization of the top surface of the component carrier 100, but in particular also a good planarization of the bottom surface (here the second main surface MS2), which allows to establish proper connections with the lower thermistor 20. This will further lead to improved heat conduction and therewith to improved heat dissipation and heat inductance into the lower thermistor 20, resulting in a higher quote of passing of the UBI test for component carriers 100 according to the present invention.

The bottom surface of the component carrier 100, here main surface MS2, may also be configured and/or comprise a connection surface.

In some embodiments, the panel 200 may be hold vice versa, i.e. with a connection surface, for example with solder balls 37, facing towards the supporting structure 300. This may in particular depend on the connection needs and the required resulting shape of the component carrier respective its stacks after the separation process.

Preferably, the panel 200 is hold during separation and deformed during separation such that the result is an advantageous shape of the separated stacks 201 respectively the resulting component carrier 100, wherein in particular a curvature of the panel 200 is adjusted during separation or for separation of the panel 200, wherein the curvature of the panel for or during separation is in particular at least partially adjusted via a holding force F, in particular by adjusting a suction force F. The curvature of the panel 200 may also be influenced by the geometry of the supporting structure 300, in particular by a supporting distance between two supporting zones or areas in which the panel is in contact with the supporting structure 300 when being hold thereon.

FIG. 6 shows an enlarged view of the right area of a separated component carrier stack 201 (respectively the resulting component carrier 100) of FIG. 5, wherein from this illustration the advantageous effect of holding the panel 200 during separation such that the panel is deformed into a concave shape is apparent, in particular the larger extension L1, in particular the larger arc length L1, of the first main surface MS1 compared to the extension L2, in particular the arc length L2, of the second main surface MS2 of said component carrier 100, and the lateral walls W1, W2 extending with an angle α different from 90° to the respective main surfaces MS1, MS2.

Preferably, the panel 200 is deformed during separation such that an extension difference 2ΔL=L1−L2 of the extension L1 of the first main surface MS1 and the second main surface MS2 is in a range from 0.02 μm up to 0.5 μm, in particular in a range of 0.1 μm up to 0.2 μm, resulting in half extension difference ΔL from 0.01 μm up to 0.25 μm respectively from 0.05 μm up to 0.1 μm.

In an advantageous embodiment, the total extension difference 2ΔL is preferably equally distributed along the respective extension direction ED as illustrated in the Figures. That means, that the extension difference ΔL is preferably the same on the left side of the component carrier 100 as it is on the right side and therewith in particular symmetrically distributed to the stacking direction.

For preferred heat conductivity properties of the resulting component carrier, in at least some embodiments, the panel 200 is arranged during separation such that the connection surface, in particular the connection surface comprising solder balls 37, is facing away from the supporting structure 300, in particular from the suction side.

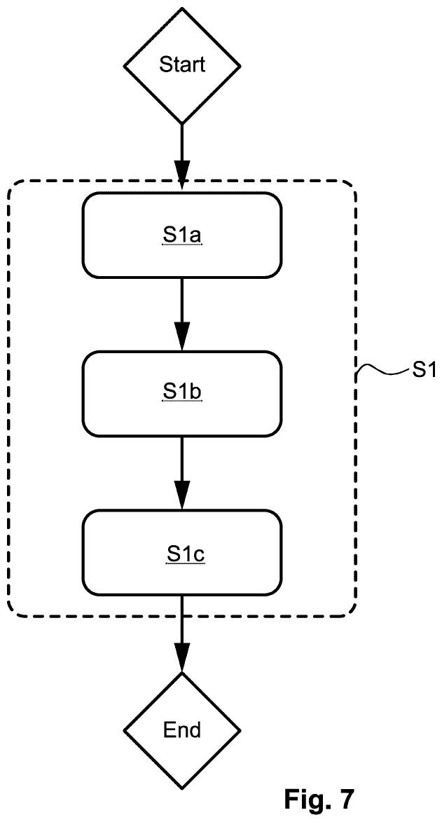

FIG. 7 shows a flow chart of an exemplary embodiment of a method for manufacturing a component carrier 100 according to the present invention, wherein in a main step S1 at least one stack 30 is provided having a stacking direction and comprising a first main surface MS1 and a second main surface MS2, wherein said first main surface MS1 and said second main surface MS2 are provided one above the other in a stacking direction and being opposed one to each other. Said at least one stack 30 further comprises a lateral wall W1 and a second lateral wall W2 between said first and second main surfaces MS1 and MS2 for connecting said opposed main surfaces MS1 and MS2.

According to the present invention, said stack comprises a first extension L1 of the first main surface MS1, which is at least in a planarized state, as illustrated for example in FIG. 2, different from an extension L2, as for example from length extension L2 of the second main surface MS2. I

In a preferred embodiment as explained in this application, said step S1 for providing said stack 30 may in particular comprise a step S1a of providing a panel 200, wherein said panel 200 comprises several component carrier stacks 201 each comprising at least one electrically conductive layer structure and at least one electrically insulating layer structure (not shown), wherein said panel 200 is configured to be divided into a plurality of component carrier stacks 201.

Said step S1 may further comprise a step S1b in which said provided panel 200 may in particular be deformed, as for example illustrated in FIG. 5, along a respective thickness direction, with respect to FIG. 5 in particular in a vertical direction, respectively in a stacking direction, for example by a suction force F and a supporting structure 300.

By said deformation step the shape of the panel 200 is changed, wherein preferably the shape is changed into a bowl shape with the opening facing away from the supporting structure 300 by which the panel is hold and by which said suction force F is applied to deform said panel 200.

As explained in detail before, the panel 200 is preferably being hold from the supporting structure 300 in the deforming step S1b such that the connection surface with the solder balls 37 is facing away from the supporting structure 300. By holding the panel like this and as illustrated in FIG. 5, and deforming the panel 200 like a bowl with the opening of the bowl facing away from the supporting structure 300 and then separating said panel 200 in a next step S1c, for example by laser grooving and or drilling, in a very easy manner a component carrier 100 according to the present invention may be provided comprising a first main surface MS1 with an extension being different from an extension of a second main surface MS2 of said component carrier 100, which comprises an improved connection capability, in particular for example with a heat sink, whereby good heat conductivity in the UBI test and good electrical connection behavior of a component carrier may be improved.

In addition to the embodiments described herein, many other advantageous embodiments are possible within the scope defined by the patent claims.

### LIST OF REFERENCE SIGNS

10 exemplary UBI-test configuration for a component carrier as known from prior art
1 component carrier as known from prior art (“IC substrate”)
2 UBI heater
3 lid
4 die
5 conductive structure
6 heater contacts
7 solder balls
8 upper contacts of the component carrier
9 upper thermistor
11 conductive structure within the component carrier
20 lower thermistor comprising thermal sensor for detecting heat conductivity from upper thermistor to lower thermistor
21 detection contact
22 detection contact
23 detection contact
24 detection contact
25 lower contacts of the component carrier
CZ1 first connection zone with bad or no connection
CZ2 second connection zone with bad or no connection
100 example of a component carrier according to the present invention
30 stack comprising a plurality of layer structure
31 layer structure
37 electrically conductive structure, in particular solder ball
38 theoretic lateral wall extending perpendicular to first and second main surfaces
200 panel
201 component carrier stacks+
202 panel carrier
210 separation means
220 laser beam
300 supporting structure, in particular chuck table
α internal angle between lateral wall and adjacent main surface
CD cutting direction
ΔL extension difference, in particular length difference between first extension (length) and second extension (length)
ED extension direction
F suction force (negative pressure, vacuum)
F1 exemplary force applied to the component carrier (by application of positive pressure on the component carrier)
F2 exemplary force applied to the component carrier (by application of negative pressure/suction on the component carrier)
L1 first extension, in particular extension length of first main surface in (first) extension direction
L2 second extension, in particular extension length of second main surface (first) extension direction
MS1 first main surface of the component carrier
MS2 second main surface of the component carrier
P1 first outmost point of the first main surface
P2 second outmost point of the first main surface
Q1 first outmost point of the second main surface
Q2 second outmost point of the second main surface
S1 method step of providing a stack for a component carrier
S1a. . . . S1c method steps including in providing step
W1 first lateral wall
W2 second lateral wall

1. A component carrier, comprising a stack with a stacking direction, said stack comprising:
at least one electrically conductive layer structure,
at least one electrically insulating layer structure,
a first main surface and a second main surface, wherein said first main surface and said second main surface are provided one above the other in a stacking direction and are opposed one to the other, and
a first lateral wall and a second lateral wall between said first main surface and said second main surface connecting said opposed first main surface and said second main surface,
wherein at least in a planarized state of said stack in at least a first extension direction an extension of the first main surface is different from an extension of the second main surface.

2. The component carrier according to claim 1, wherein at least in the planarized state of said stack, the extension of the first main surface is greater than the extension of the second main surface or vice versa.

3. The component carrier according to claim 1, wherein at least one of said first main surface and said second main surface of said stack is not planar, wherein in particular both the first main surface and the second main surface are not planar.

4. The component carrier according to claim 1, wherein the first main surface has a concave shape in the stacking direction.

5. The component carrier according to claim 4, wherein the second main surface or the first main surface has a convex shape in the stacking direction.

6. The component carrier according to claim 1, wherein at least one of the first lateral wall and the second lateral wall extends away from at least one of the first main surface and the second main surface with an internal angle (α) between said first lateral wall and said second lateral wall and the respective main surface of the first main surface and the second main surface being different from 90°.

7. The component carrier according to claim 6, wherein the first lateral wall and the second lateral wall are inclined relative to at least one of the main surfaces with an internal angle between said first lateral wall and said second lateral wall and the respective main surface of the first main surface and the second main surface is in a range from 90.001° to 90.05°.

8. The component carrier according to claim 1, wherein in at least one extension direction of said stack an arc length of the first main surface is different from an arc length of the second main surface in said extension direction, wherein, in particular, an arc length difference between the arc length of the first main surface in at least one extension direction of said stack and the arc length of the second main surface in said extension direction is in a range from 0.02 to 0.5 μm.

9. The component carrier according to claim 1, wherein a first extension in a first extension direction of the first main surface is different from a first extension of the second main surface in said first extension direction, and wherein a second extension in a second extension direction of the first main surface is different from a second extension of the second main surface in said second extension direction, wherein the second extension direction is different from the first extension direction, in particular extending in a common plane with the first extension direction and perpendicular to said first extension direction.

10. The component carrier according to claim 1, wherein in at least a first extension direction of the first main surface and the second main surface a first extension difference between a first extension of the first main surface and a first extension of the second main surface in said first extension direction is in a range from 0.02 to 0.5 μm.

11. The component carrier according to claim 10, wherein in at least a second extension direction of the first main surface and the second main surface a second extension difference between a second extension of the first main surface and a second extension of the second main surface in said second extension direction is not equal to the first extension difference, and wherein the second extension direction is different from the first extension direction.

12. The component carrier according to claim 1, wherein at least one of the first main surface and the second main surface comprises one or more connection surfaces configured for establishing an electrical connection with at least one external component.

13. The component carrier according to claim 12, wherein the first main surface has a concave shape, the second main surface has a convex shape, and one or both of the first main surface and the second main surface comprises at least one respective connection surface.

14. The component carrier according to claim 12,, wherein at least one connection surface comprises one or more solder balls and/or pillars being electrically connected to said respective connection surface.

15. A method for manufacturing a component carrier according to claim 1, the method comprising:
providing at least one stack having a stacking direction said stack comprising:
at least one electrically conductive layer structure,
at least one electrically insulating layer structure,
a first main surface, and
a second main surface, wherein said first main surface and said second main surface are provided one above the other in a stacking direction and being opposed one to the other; and
forming a first lateral wall and a second lateral wall between said first main surface and said second main surface connecting said opposed first main surface and second main surface;
wherein at least in a planarized state of said stack an extension of the first main surface is different from an extension of the second main surface.

16. The method according to claim 15, wherein providing of said at least one stack further comprises:
providing a panel comprising a panel stack comprising the at least one electrically conductive layer structure and the at least one electrically insulating layer structure;
deforming the panel along the stack direction thereby changing a planar shape of at least one main surface of said panel; and
separating the deformed panel into a plurality of sub-panels or single stacks, in particular by dicing the deformed panel.

17. The method according to claim 16, wherein the panel is deformed such that is has, at least partially, a curved shape.

18. The method according to claim 16, further comprising holding the deformed panel on a supporting structure using a vacuum while separating the deformed panel into the plurality of sub-panels or single stacks.

19. The method according to claim 18, wherein the panel comprises at least one connection surface and the panel is held on said supporting structure while separating the deformed panel into the plurality of sub-panels or single stacks such that said connection surface is facing away from said supporting structure.

20. The method according to claim 18, wherein holding the deformed panel on said supporting structure using said vacuum comprises holding the panel with a concave side of the panel facing away from said supporting structure.
